(19) United States
(12) Patent Application Publication
(10) Pub. No.: US 2009/0220680 A1
(43) Pub. Date: Sep. 3, 2009

(54) OLED DEVICE WITH SHORT REDUCTION

(76) Inventor: Dustin L. Winters, Webster, NY (US)

Correspondence Address: Frank Pincelli;Patent Legal Staff, Eastman Kodak Company, 343 State Street, Rochester, NY, 14650-2201, US

(21) Appl. No.: 12/039,970

(22) Filed: Feb. 29, 2008

(51) Int. Cl. B05D 5/12

(52) U.S. Cl. 427/66

(57) ABSTRACT

A method of making an OLED device includes providing a substrate having a first electrode into a controlled environment; baking the substrate in the controlled environment to remove moisture; forming an inorganic short reduction layer over the moisture reduced substrate in the controlled environment after baking the substrate, such short reduction layer having a resistivity greater than the resistivity of the first electrode; forming an organic electroluminescent media over the moisture reduced substrate in the controlled environment; forming a second electrode over the organic electroluminescent media in the controlled environment wherein the OLED device is formed; and encapsulating the OLED device.

### CROSS REFERENCE TO RELATED APPLICATION

Reference is made to commonly assigned U.S. patent application Ser. No. 11/734,485 filed Apr. 12, 2007, entitled “OLED Device With Short Reduction” by Dustin Winters et al, the disclosure of which is incorporated herein.

### FIELD OF THE INVENTION

The present invention relates to short reduction in OLED devices and displays.

### BACKGROUND OF THE INVENTION

In the simplest form, an organic electroluminescent (EL) device is includes an organic electroluminescent media disposed between first and second electrodes serving as an anode for hole injection and a cathode for electron injection. The organic electroluminescent media supports recombination of holes and electrons that yields emission of light. These devices are also commonly referred to as organic light-emitting diodes, or OLEDs. A basic organic EL element is described in U.S. Pat. No. 4,356,429. In order to construct a pixelated OLED display device that is useful as a display such as, for example, a television, computer monitor, cell phone display, or digital camera display, individual organic EL elements can be arranged as pixels in a matrix pattern. These pixels can all be made to emit the same color, thereby producing a monochromatic display, or they can be made to produce multiple colors such as a three-pixel red, green, blue (RGB) display. OLED display devices have also been fabricated with active matrix (AM) driving circuitry in order to produce high performance displays. An example of such an AM OLED display device is disclosed in U.S. Pat. No. 5,550,066.

The organic electroluminescent media of AM OLED devices are frequently fabricated in a large, vacuum systems. These vacuum systems are designed to create a controlled environment with a low concentration of moisture and oxygen. This is because the typical organic electroluminescent element is degraded by the presence of moisture. An example of a typical manufacturing tool for producing AM OLED devices having such a vacuum system is shown in Japanese Patent Application JP2006260939(A). As can be seen in Japanese Patent Application JP2006260939(A) it is often desirable to include a baking chamber for removing moisture that may be trapped in the substrate or active matrix circuitry layers prior to forming the organic electroluminescent layers. Such trapped moisture can result in degradation of the OLED device over extended durations of use or storage. Typical baking processes can last for 2 or more hours and be in the temperature range of 200° C. to 250° C.

When manufacturing organic EL displays, problems such as particle contamination or scratches in the organic EL materials can result in defects in a display. One type of defect that is caused by particle contamination or scratches is a short circuit through the thin organic materials, connecting the anode and the cathode. A short between the anode and cathode results in a non-emitting pixel (dead pixel) or a pixel that emits at reduced brightness (dim pixel). A structure for improving robustness against shorting defects is described by Tyan et al. in U.S. Pat. No. 7,183,707. Tyan et al. describe inclusion of an inorganic short reduction layer disposed between the organic electroluminescent media and one of the electrodes. The short reduction layer has a particular electrical resistivity and thickness to reduce leakage current through a shoring defect. Several useful materials are described including Molybdium oxides as well as mixtures of partially conducting metal oxides with insulating oxides, fluorides, and sulfides.

However, it has been found that short reduction layers are degraded when subject to baking. Therefore, a new manufacturing system and method is required for producing OLED devices having short reduction layers and also having low trapped moisture.

### SUMMARY OF THE INVENTION

It is an object of the present invention to provide an improved method of producing an OLED display device having a short reduction layer. It is a further object of the present invention to reduce degradation of the short reduction layer during the production process. It is a further object of the present invention to reduce moisture or solvent contamination to the OLED display device thereby reducing damage to the organic electroluminescent element.

These objects are achieved by a method of making an OLED device including:

(a) providing a substrate having a first electrode into a controlled environment;

(b) baking the substrate in the controlled environment to remove moisture;

(c) forming an inorganic short reduction layer over the moisture reduced substrate in the controlled environment after baking the substrate, such short reduction layer having a resistivity greater than the resistivity of the first electrode;

(d) forming an organic electroluminescent media over the moisture reduced substrate in the controlled environment;

(e) forming a second electrode over the organic electroluminescent media in the controlled environment wherein the OLED device is formed; and

(f) encapsulating the OLED device.

### BRIEF DESCRIPTION OF THE DRAWINGS

FIG. 1 is a cross-sectional view of a portion of a pixel of an OLED device according to the present invention;

FIG. 2 is a block diagram showing a method of making an OLED device according to the present invention; and

FIG. 3 is a manufacturing system useful in producing the OLED device according to the present invention.

Since some device feature dimensions such as layer thicknesses are frequently in sub-micrometer ranges, the drawings are scaled for ease of visualization rather than dimensional accuracy.

### DETAILED DESCRIPTION OF THE INVENTION

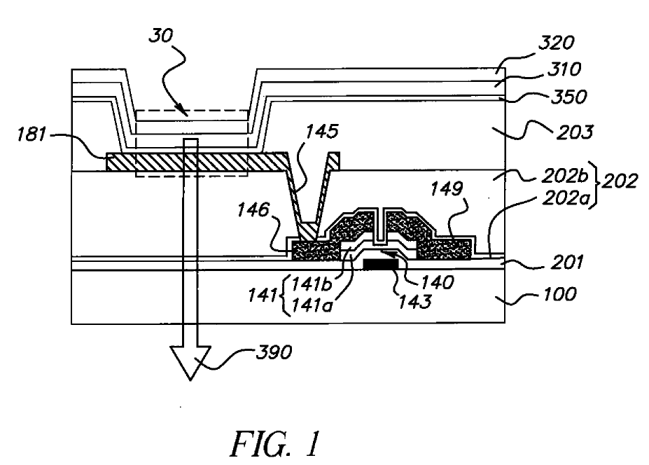

An OLED device having a short reduction layer according to the present invention is shown in FIG. 1. This illustration shows a cross-section of a portion of a pixel of an active matrix type display. The OLED device includes an OLED element 30, which is driven by transistor 140. Transistor 140 is a portion of active matrix drive circuitry such as is commonly used to drive OLED displays and is well known in the art. Other examples of such active matrix type OLED devices can be found in U.S. Patent Application Publication 2007-0257606A1. Use of active matrix circuitry represents one embodiment of the present invention. However, the present invention is not limited to active matrix type OLED devices and can also be practiced with OLED devices not driven by active matrix circuitry (i.e. passive matrix type OLED devices) by one skilled in the art.

The OLED device is fabricated over a substrate 100. Useful substrates include substrates made of glass such as Corning 1737® or Corning Eagle® type glass. Other substrates are known for use with OLED devices including metal foils (such as stainless steel foils), silicon wafers, and plastic substrates. Such substrate materials can also be used in the present invention by one skilled in the art. The use of opaque substrates can be employed if the OLED device is made to emit light in the direction opposite to the substrate (i.e. a top emission configuration).

The transistor driving portion of the OLED device will now be described in more detail. Many different types of transistors for driving OLED devices are well known in the art. A bottom gate type amorphous silicon based transistor is shown here. The construction of such transistors is known in the art. The present invention is not limited to this type of driving transistor and many other driving transistors included poly-silicon based and top gate type transistors can also be used. Transistor 140 is formed over substrate 100. Various barrier layers (not shown) including, for example, silicon nitride or silicon oxide can be employed between the substrate 100 and transistor 140 if desired as is known in the art. Transistor 140 is formed of three terminals; a gate 143, a terminal 146, and a terminal 149. Gate 143 is formed of a conductive material such as Cr, Mo, Al, or the like. Terminals 146 and 149 can be configured, for example, as either source or drain terminals depending on the polarity of the OLED element and the rest of the active matrix pixel drive circuit (not shown). Terminal 149 can also be formed as part of a power line (not shown), which supplies current to the OLED element. Transistor 140 also includes a semiconductor 141. Terminals 146 and 149 include a conductor such as aluminum, or an aluminum alloy such as Al:Nd, or can also be formed of stacks of conductive material such as Al or Al:Nd stacked with Mo, Cr, Ti or the like. Semiconductor 141 can include, for example, amorphous silicon. Semiconductor 141 is composed of doped region 141b and un-doped region 141a. Semiconductor 141 is spaced from gate 143 by an insulator layer 201 which can be formed of, for example, silicon nitride or the like. Over transistor 140 an insulator layer 202 is formed. Insulator layer 202 includes a barrier sub-layer 202a formed of, for example, an inorganic layer such as silicon nitride. Insulator layer 202 also includes a planarizing sub-layer such as a planarizing sub-layer 202b which can be formed of, for example, a photo-patternable organic material or the like. Alternately, insulator layer 202 can also be formed of more or less sub-layers. An opening 145 is formed in insulator layer 202 to permit electrical connection to terminal 146 of transistor 140.

Over insulator layer 202, a lower electrode 181 is formed. The lower electrode 181 can be formed of Indium Tin Oxide (ITO) or other transparent conductive oxides such as Indium Zinc Oxide (IZO), Aluminum doped Zinc Oxide (AZO), or the like. Such transparent lower electrode materials when used in combination with a transparent substrate 100 such as glass permit light emission from the OLED device to be viewed through the substrate. This configuration is known as a bottom emission configuration. Alternate configurations where the light emission is viewed from the opposition direction (referred to as a top emission configuration) or in both directions (referred to as a dual emission configuration) are also known in the art and can be applied to the present invention. The lower electrode can be configured as the anode of the OLED element 30 but arrangements where the lower electrode is alternately configured as the cathode of the organic light emitting diode are known in the art and can be applied to the present invention. The edges of lower electrode 181 are covered with an insulator layer 203. This insulator layer 203 can be constructed, for example, of an photo-patterned polymer and serves to prevent high electric fields at the edges of the lower electrode 181. Similar insulator layers for this purpose are described in U.S. Pat. No. 6,246,179. Use of insulator layer 203 is useful, but not required for successfully practicing the present invention.

A short reduction layer 350 is formed over the lower electrode 181. A preferred composition of the short reduction layer is a mixture of Indium Tin Oxide (ITO) and Zinc Sulfide (ZnS) Silicon Dioxide (SiO₂) (this mixture will be hereafter referred to as ZSO). The short reduction layer can be formed by co-sputtering from a first ITO sputter target and a second ZSO sputtering target. Alternately, the various component materials can be mixed into single, compound sputter target. Other materials useful for the short reduction layer are described in U.S. Patent Application Publication 2005-0225234 A1.

Above short reduction layer 120, an organic electroluminescent medium 310 is formed. There are many different organic electroluminescent media configurations known in the art which can be successfully applied to the present invention by one skilled in the art. Although the organic electroluminescent medium 310 is shown as a single layer, it preferably includes a plurality of sub-layers such as a hole transporting sub-layer and an electron transporting sub-layer. Organic electroluminescent medium 310 can include additional sub-layers such as hole injecting sub-layers and light emitting sub-layers. For example, a basic two-layer electroluminescent medium device structure is described in U.S. Pat. No. 4,356,429. One exemplary configuration of organic electroluminescent medium 310 includes a hole transporting sub-layer including NPB (4,4′-Bis[N-(1-naphthyl)-N-phenylamino]biphenyl) and an electron transporting sub-layer including AlQ (tris(8-hydroxyquinoline)aluminum). Additionally, it is often useful to provide a hole-injecting sub-layer between the anode and the hole transporting sub-layer. The hole-injecting material can serve to facilitate injection of holes into the hole-transporting layer. There are a wide variety of hole injecting materials known in the art. Hexaazatriphenylene derivatives are useful as hole-injecting materials, as described in U.S. Pat. No. 6,720,573. Particularly useful compounds include hexaazatriphenylene derivatives according to formula K-1 below wherein each R is independently or simultaneously selected from the group consisting of hydrogen atom, C1-12 s hydrocarbon, halogen, alkoxy, arylamine, ester, amide, aromatic hydrocarbon, heterocyclic compound, nitro, and nitrile (—CN) group.

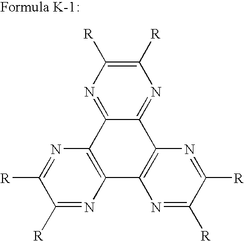

One particularly useful hole-injecting hexaazatriphenylene derivative is hexacyanohexaazatriphenylene (CHATP), shown below as formula K-2:

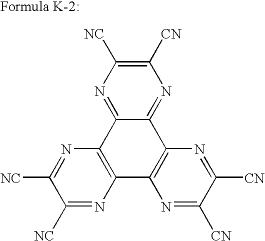

Over organic electroluminescent medium 310, an upper electrode 320 is formed. Although shown as a single layer, upper electrode 320 can also include a plurality of sub-layers. Several upper electrode configurations are known in the art and can be applied to the present invention by one skilled in the art. One configuration for upper electrode 320 includes a sub-layer of Li or LiF approximately 0.5 nm thick in contact with the organic electroluminescent medium 310 for facilitating electron injection followed by a sub-layer of Al approximately 100 to 400 nm thick. Other features such as a moisture barrier encapsulation (not shown) or desiccant (not shown) commonly used in the art of fabricating OLED devices can also be included. The OLED element 30 is formed of organic electroluminescent media 310, lower electrode 181 and upper electrode 320 defined by the opening in insulator layer 203. Application of an electric field between the lower electrode 181 and upper electrode 320 will cause OLED element 30 to generate light emission 390.

As taught by Tyan et al. in U.S. Patent Application Publication 2005-0225234 A1, the short reduction layer 350 reduces the leakage current through small, localized shorts, such as shorts caused by particle contamination, by introducing a resistive component in the path of the short between the electrodes. The short reduction layer is highly resistive, having a resistivity greater than the first and second electrodes. It is desirable that the short reduction layer 350 be of high enough resistance to reduce the undesirable leakage current through the short to less than the current flowing through the functional OLED element 30. However, if the short reduction layer is too resistive, the current flow through the entire OLED element 30 will be impaired, thereby resulting in increased operating voltage. On the other hand, if the resistance of the short reduction layer is too low, lateral current flow will occur in the short reduction layer, which can result in cross-talk between neighboring emitting areas or pixels. Tyan et al, further teach that the required resistivity of the short reduction layer for reduction of current is dependent on the size of the emitting elements and the current being driven through the OLED element with a goal of reducing the current through the short to about 10% or less of the current flowing through the OLED. The current flow through the short is also dependent on the area of the short. Tyan et al. describes an example defect area of about 1 micrometer×1 micrometer. However, actual defects can be significantly smaller, for example 0.1 micrometer×0.1 micrometer or smaller.

For a typical high resolution display application, the emitting area of each pixel can be approximately 0.1 mm×0.1 mm or 1×10⁻⁴ cm². Peak pixel currents for a typical OLED display can be between 1 and 10 mirco-amperes (μA). Therefore, the peak current density is approximately 10 to 100 mA/cm². The short reduction layer is preferably constructed with a thickness of between 2 nm and 500 nm and more preferably between 20 nm and 200 nm.

For purposes of this invention, tie preferred upper limit for resistivity of the short reduction will be considered the resistance beyond which significant voltage drop occurs when operated at peak current. Since OLED elements typically operate at voltage of between 3 V and 20 V depending on the efficiency and layer construction, a significant amount of voltage can be considered 2 V of additional voltage.

The resistance of the shorting reduction layer (R) for a given pixel can be determined from the following equation:

$$R = \frac{ρ \times t}{{A}_{pixel}} \qquad ( equation 1 )$$

where ρ is the resistivity, t is the layer thickness of the short reduction layer, and Aₚᵢₓₑₗ is the emitting area of pixel. The voltage (V) across the short reduction layer in operating areas (excluding the shorting areas) can then be found from the following equation:

V=I_{D}×ρ×t (equation 2)

where I_{D} is the current density per unit area.

As can be seen from equation 2, the voltage drop is related to the current density, but not directly to the area of the pixel. Therefore, the voltage limit is not dependent on the size of the pixel. To achieve a preferred upper limit of the 2 V and at a thickness of 20 nm and peak current density of 10 mA/cm², the resistivity of the short reduction layer should preferably be less than or equal to 1×10⁸ ohm*cm. More preferably, to achieve a voltage rise of less than 0.2 V, the upper limit of resistivity should be less than 1×10⁷ ohm*cm.

The preferred lower limit is similarly depended on the specifics of the application. The short reduction layer is more resistive than either the upper or lower electrodes of the OLED device. For example, indium tin oxide (ITO) which is typically used for a lower electrode commonly has a resistivity of 5×10⁻⁴ ohm*cm or less. As previously described, the short reduction layer preferably reduces current through the short to less than 10% of the normal pixel operating current. The lower limit of resistivity can then be found from the following equation:

$${ρ}_{lower} = \frac{V \times {A}_{short}}{{I}_{limit} \times t} \qquad ( equation 3 )$$

where Iₗᵢₘᵢₜ is the desired limit of current to be permitted through the short and Aₛₕₒᵣₜ is the area of the short. Taking the case of a pixel with a 200 nm thick short reduction layer, 0.1 micrometer×0.1 micrometer short, operating at 10 V, and permitting a limit of 10% of 10 microamperes of peak current, the short reduction layer would preferably have a resistivity of greater than 50 ohm*cm. More preferably, for a case where the short reduction layer with a thickness of 20 nm and a current limit of 10% of 1 microampere, the resistivity of the short reduction should be greater than 5×10³ ohm*cm. In a case where the short area was further increased to 1 micrometer by 1 micrometer, a lower limit of 5×10⁵ ohm*cm can be imposed.

It is also desirable to limit pixel to pixel cross-talk if the short reduction layer is to be applied across multiple pixels without precision patterning. The exact requirements again depend on the details of the design, such as pixel dimensions and spacing, operating currents, and pixel driving circuits. In this case, the short reduction layer should be of sufficient resistivity to limit any cross talk effects.

An example film useful for a short reduction layer will now be described. A short reduction layer film (Sample S1) was prepared by sputtering from a single target two inch diameter including 68.3% In₂O₃, 20.9% ZnS, 7.6% SnO₂, and 3.2% SiO₂ by weight. The sputtering was performed at an ambient pressure of approximately 4.5 milliTorr while flowing a gas mixture of 5.2% oxygen in argon. An RF magnetron source was used to power the sputter target at 80 Watts. Comparative films (Samples C1, C2, and C3) were also simultaneously prepared and then subsequently subjected to baking for a duration of two hours at temperatures of 220° C., 130° C., and 80° C. The resulting resistance properties of the films are listed below in Table 1.

TABLE 1

| | | | Sheet | | |
|---|---|---|---|---|---|
| | Bake | Bake | Resistance | Thickness | Resistivity |
| Sample | Temp (C.) | Time (hr) | (ohm/sq) | (nm) | (ohm * cm) |
| S1 | No | | 8.3E+09 | 48.5 | 4.0E+04 |
| C1 | 80 | 2 | 1.0E+09 | 48.5 | 4.9E+03 |
| C2 | 130 | 2 | 1.1E+09 | 48.5 | 5.3E+03 |
| C3 | 220 | 2 | 2.7E+08 | 48.5 | 1.3E+03 |

As can be seen from Table 1, the process of baking caused a change in the film properties resulting in a loss or reduction of resistivity of the comparative samples over sample A. The loss or reduction of resistivity is shown in the comparative samples to be less effective in reducing current flow through a shorting defect. Also if used in a configuration where the short reduction layer is applied over a plurality of pixels without precision patterning, current flow between pixels will increase, resulting in undesirable pixel to pixel cross talk. As such, it was determined that substrates having the short reduction layer should not be subsequently baked and therefore the OLED manufacturing tool and process for making OLED devices such as taught in previously described Japanese Patent Application JP2006260939(A) is not suitable for use with OLED devices having this short reduction layer film.

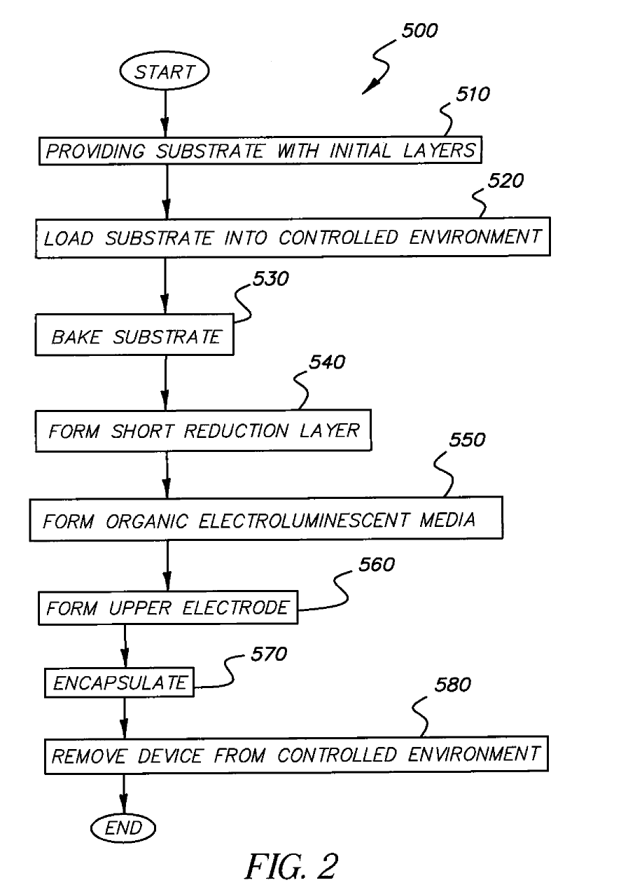

Turning now to FIG. 2, a block diagram illustrating fabrication process 500 for making an OLED device according to the present invention will now be described. Fabrication process 500 includes providing substrate 100 initial layers (step 510). These initial layers include lower electrode 181, insulator layer 203, insulator layer 202, and all the layers providing active matrix circuitry such as transistor 140 including insulator 201. Fabrication processes for producing these layers, including transistor 140 are known in the art.

The substrate 100, including these initial layers, is then loaded into a controlled environment (step 520). The controlled environment is an environment that contains an inert ambient gas such as nitrogen, argon, or like or an environment that is maintained at a reduced pressure (vacuum) such as less than 133 Pa and preferably less than 0.133 Pa and more preferably less than 0.133 mPa. The controlled environment can be a dry box, vacuum chamber, or a plurality of dry boxes and/or vacuum chambers either directly connected or linked by way of a transfer vessel. The controlled environment can vary during the manufacturing process. For example, the controlled environment can change from a reduced pressure environment to a nitrogen environment by means of connected environmental chambers. For purposes of this disclosure, any such connected controlled environments are considered together as “a controlled environment”. The preferred controlled environment is a sealed vacuum vessel cluster system or and in-line vacuum vessel system. This controlled environment is beneficial to the subsequent deposition of the organic electroluminescent media materials, which are known to degrade in the presence of moisture and oxygen.

The substrate is then baked (step 530) at an elevated temperature and for an extended duration while in the controlled environment. For example, the substrate could be baked for at 220° C. for 2 hours. This baking step is performed in order to remove moisture trapped on the surface of the substrate or absorbed into any of the layers in the substrate. For example, layers that include organic materials such as insulator layer 203 and planarizing sub-layer 202b of insulator layer 202, tend to absorb moisture which can be trapped until released during the bake step (step 530). Moisture or oxygen trapped in the final OLED device can degrade the OLED element over time. Therefore, to reduce such degradation, it is necessary to remove much of the trapped moisture through baking. Following baking, the substrate remains in the controlled environment until the device is encapsulated in order to keep the amount of moisture subsequently absorbed low.

Next, the short reduction layer is formed (step 540). This is done, for example, by sputter deposition as previously described. It has been observed by the present inventor that once formed, the short reduction layer can change when exposed to elevated temperatures. For example, as described above, it has been observed that the resistivity of the short reduction layer can be reduced by a factor of 10 to 1000. Such loss of resistivity renders the short reduction layer in effective for its role in reducing shorting defects. Therefore, according to the present invention, the formation of the short reduction layer (step 540) is performed after moisture is removed during baking (step 530) and while within the controlled environment. This arrangement provides for removal of trapped moisture while also avoiding degradation of the short reduction layer. Optionally, in order to provide for good control of the short reduction layer deposition, the substrate can be cooled following baking (step 530) and before formation of the short reduction layer (step 540). Such cooling can be passive (i.e. by waiting for a duration) or active (i.e. by reducing the ambient temperature or providing a cooled heat sink). The short reduction layer can also be deposited through a shadow mask so as to form the short reduction only over the light emitting areas of the display and not, for example over the preferable areas of the display where external electrical connections are made.

While in the controlled environment, the organic electroluminescent media 310 is formed over the substrate in step 550. As previously described, the electroluminescent media 310 is preferably constructed of a plurality of sub-layers including a plurality of different organic materials. One preferred method for depositing these organic electroluminescent media materials is by heating a plurality of sources, such as graphite boats or crucibles, containing the organic materials such that the material evaporates or sublimates and condenses over the short reduction layer 350, lower electrode 181 and substrate 100. The organic electroluminescent media materials can be deposited through a shadow mask so as to be formed only over the light producing areas of the display device and not the peripheral areas, which can be used for making external electrical connections. Alternate methods of depositing the organic electroluminescent media materials are known in the art, examples of which include laser transfer from a donor substrate.

Next, while still in the controlled environment, upper electrode 320 is formed (step 560). The upper electrode 320 can be formed by several known methods such as evaporation or sputtering. The upper electrode materials can also be deposited through a shadow mask so as to be formed only over the light producing areas and not the peripheral areas of substrate 100 since the peripheral areas.

The device is then subsequently encapsulated (step 570) while in the controlled environment. A variety of encapsulation methods are known in the art and can be applied to the present invention. For example, a sealing member made of glass or metal can be attached to the substrate using an adhesive. This step can include providing desiccant within the encapsulated device to further reduce moisture and oxygen which can attack the OLED element. Alternately, thin film encapsulation methods where low moisture permeability films are formed over the upper electrode are formed. Some examples of thin film encapsulations applied to OLED devices including layers of Aluminum Oxide deposited by an atomic layer deposition (ALD) method followed by a Parylene layer as described in U.S. Patent Application Publications US 2001/0052752 A1 and US 2002/0003403 A1. Once the device has been encapsulated, it can safely be removed from the controlled environment (step 580).

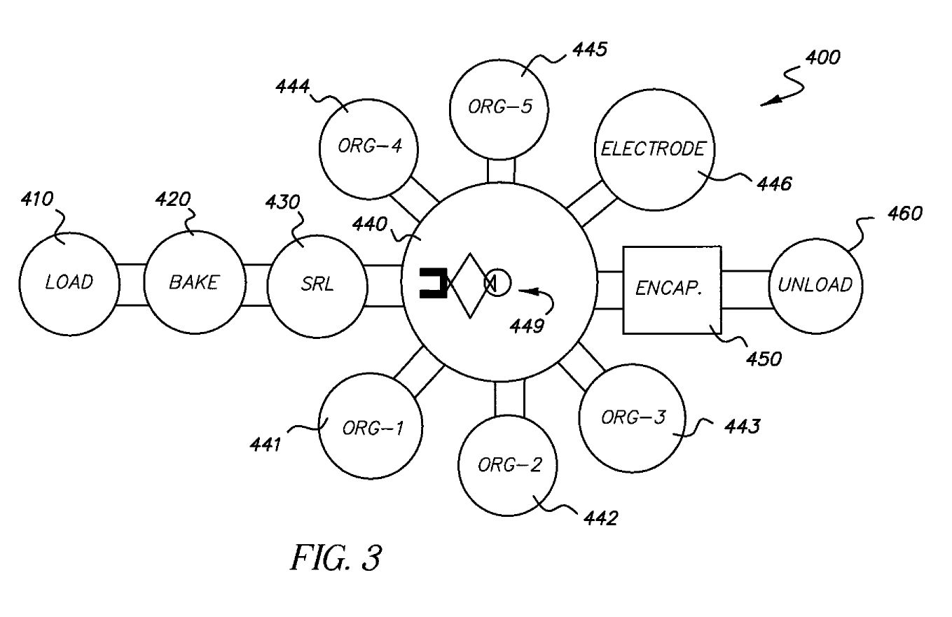

Turning now to FIG. 3, a manufacturing tool 400 useful for practicing the present invention is shown. Manufacturing tool 400 includes several vacuum chambers for maintaining a controlled environment located around a central chamber 440. Central chamber 440 contains a transfer robot 449 for moving substrates between chambers. A load chamber 410 is used to load substrates into a controlled environment (step 520). For a reduced pressure controlled environment, load chamber 410 includes a vacuum pump. Load chamber 410 can optionally hold a plurality of substrates. Next the substrate is moved into a bake chamber 420. Optionally, a plurality of substrates can be moved into the bake chamber 420 at once. In an alternate configuration, the function of the load chamber 410 and bake chamber 420 can be combined into a single chamber. In the bake chamber 420, the substrates are brought to an elevated temperature (step 530), such as 220° C. The heating can be accomplished s by methods such as radiative heating or convective heating in a nitrogen, argon, or helium environment. The baking serves to remove moisture from the substrate as previously described to achieve a low moisture state. The substrate can optionally be cooled as described above.

The substrate is then moved into a chamber 430 for deposition of the short reduction layer (step 540). During this time, the substrate is maintained in the controlled environment to maintain the low moisture state achieved by the baking (step 530). Chamber 430 includes a sputter source for depositing the short reduction layer 350 over the substrate. The deposition can occur selectively through a shadow mask as previously described.

Next, the substrate is moved by way of transfer robot 449 in chamber 440 into one or more of the organic deposition chambers 441, 442, 443, 444, and 445 under the controlled environment for depositing a plurality of organic sub-layers of the organic electroluminescent media 310 (step 550). The organic deposition chambers can each contain one or more evaporation sources (or boats) for evaporating organic materials onto the substrate. The organic sub-layers can be deposited on selective areas of the substrate through shadow masks loaded in each organic deposition chamber. Next, the substrate is moved by way of transfer robot 449 into an electrode deposition chamber 446 for deposition of the upper electrode 320 (step 560). The electrode deposition chamber 446 can contain one or more evaporation sources or sputter sources for depositing the transparent upper electrode material. The substrate is then moved under the controlled environment by way of transfer robot 449 into an encapsulation chamber 450. The encapsulation (step 570) is achieved by sealing the OLED device with a sealing member, such as a glass or metal plate attached with adhesive. Following encapsulation, the substrate is moved into an unload chamber 460 where the substrate can be safely removed from the controlled environment (step 580).

The invention has been described in detail with particular reference to certain preferred embodiments thereof, but it will be understood that variations and modifications can be effected within the spirit and scope of the invention.

PARTS LIST

| | |
|---|---|
| 30 | OLED element |
| 100 | substrate |
| 140 | transistor |
| 141 | semiconductor |
| 141a | un-doped region |
| 141b | doped region |
| 143 | gate |
| 145 | opening |
| 146 | terminal |
| 149 | terminal |
| 181 | electrode |
| 201 | insulation layer |
| 202 | insulator layer |
| 202a | barrier sub-layer |
| 202b | planarizing sub-layer |
| 203 | insulator layer |
| 310 | electroluminescent media |
| 320 | upper electrode |
| 350 | short reduction layer |
| 390 | light emission |
| 400 | manufacturing tool |
| 410 | load chamber |
| 420 | bake chamber |
| 430 | chamber |
| 440 | chamber |
| 441 | organic deposition chamber |
| 442 | organic deposition chamber |
| 443 | organic deposition chamber |
| 444 | organic deposition chamber |
| 445 | organic deposition chamber |
| 446 | electrode deposition chamber |
| 449 | transfer robot |
| 450 | encapsulation chamber |
| 460 | unload chamber |
| 500 | fabrication process |
| 510 | step |
| 520 | step |
| 530 | step |
| 540 | step |
| 550 | step |
| 560 | step |
| 570 | step |
| 580 | step |

1. A method of making an OLED device including:
(a) providing a substrate having a first electrode into a controlled environment;
(b) baking the substrate in the controlled environment to remove moisture;
(c) forming an inorganic short reduction layer over the moisture reduced substrate in the controlled environment after baking the substrate, such short reduction layer having a resistivity greater than the resistivity of the first electrode;
(d) forming an organic electroluminescent media over the moisture reduced substrate in the controlled environment;
(e) forming a second electrode over the organic electroluminescent media in the controlled environment wherein the OLED device is formed; and
(f) encapsulating the OLED device.

2. The method of claim 1 wherein the short reduction layer is formed by sputtering from one or more targets.

3. The method of claim 2 wherein the short reduction layer is sputtered from one target.

4. The method of claim 1 wherein the short reduction layer comprises one or more of In₂O₃, ZnS, SnO₂ and SiO₂.

5. The method of claim 1 wherein the resistivity of the short reduction layer is between 50 and 1×10⁸ ohm*cm.

6. The method of claim 5 wherein the resistivity of the short reduction layer is greater than 5×10³ ohm*cm.

7. The method of claim 5 wherein the resistivity of the short reduction layer is less than 1×10⁷ ohm*cm.

8. The method of claim 1 wherein the controlled environment is provided by a vacuum apparatus having one or more chambers.

9. The method of claim 1 wherein the baking is performed at a temperature between 80° C. and 220° C.
